(19) United States
(12) Patent Application Publication
(10) Pub. No.: US 2022/0113594 A1
(43) Pub. Date: Apr. 14, 2022

(54) DISPLAY PANEL AND ELECTRONIC DEVICE

(71) Applicant: Shenzhen China Star Optoelectronics Semiconductor Display Technology Co., Ltd., Shenzhen, Guangdong (CN)

(72) Inventor: Su PAN, Shenzhen, Guangdong (CN)

(21) Appl. No.: 16/954,048

(22) PCT Filed: Jun. 2, 2020
(86) PCT No.: PCT/CN2020/094021

§ 371 Date: Jun. 16, 2020

(30) Foreign Application Priority Data
Apr. 1, 2020 (CN) 202010248371.7

(51) Int. Cl. G02F 1/13357; G02F 1/1341; G02F 1/1337; G02F 1/1335; H01L 27/32

(52) U.S. Cl. CPC G02F 1/133617; G02F 1/1341; G02F 1/1337; G02F 2201/44; G02F 1/133512; H01L 27/3232; G02F 2202/36; G02F 1/133514

(57) ABSTRACT

A display panel and an electronic device are provided. The display panel includes a first pixel unit, a second pixel unit, and a liquid crystal layer including a plurality of liquid crystal units. Each of the first pixel unit and the second pixel unit corresponds to one of the liquid crystal units. The liquid crystal unit corresponding to the first pixel unit is doped with a plurality of first quantum rods and a chiral molecule, and the liquid crystal unit corresponding to the second pixel unit is doped with a plurality of second quantum rods.

### FIELD

The present disclosure relates to the field of display technologies, and more particularly, relates to a display panel and an electronic device.

### BACKGROUND

Quantum dots are nanoscale-sized semiconductor particles which can emit light with a specific wavelength under an electric field or light irradiation. By adjusting particle diameters of the quantum dots, they can emit red light, green light, or blue light. Due to certain characteristics, such as having a narrow spectrum and high color saturation, the quantum dots can be used as a light conversion layer in display panels, which broadens a color gamut of the display panels.

To reduce reflection caused by metal electrodes, a circular polarizer needs to be disposed in conventional quantum dot display devices, thereby enhancing contrast. However, the circular polarizer may reduce a brightness of a display panel by approximately 50%, resulting in a low-brightness display device.

Therefore, it is necessary to provide a display panel and an electronic device to solve the above problem.

### SUMMARY

An objective of the present disclosure is to provide a display panel and an electronic device to increase a brightness of display panels.

To solve the above technical problem, the present disclosure provides a display panel, including:

a display area, wherein the display area at least includes a first pixel unit and a second pixel unit; and

a liquid crystal layer including a plurality of liquid crystal units, wherein each of the first pixel unit and the second pixel unit is correspondingly provided with the liquid crystal unit, the liquid crystal unit corresponding to the first pixel unit is doped with a plurality of first quantum rods and a chiral molecule, and the liquid crystal unit corresponding to the second pixel unit is doped with a plurality of second quantum rods.

The present disclosure further provides an electronic device, including the above display panel.

A display panel and an electronic device are provided by the present disclosure. The display panel includes a display area at least including a first pixel unit, a second pixel unit, and a liquid crystal layer. The liquid crystal layer includes a plurality of liquid crystal units. Each of the first pixel unit and the second pixel unit corresponds to one of the liquid crystal units. The liquid crystal unit corresponding to the first pixel unit is further doped with a plurality of first quantum rods and a chiral molecule, and the liquid crystal unit corresponding to the second pixel unit is further doped with a plurality of second quantum rods. Since the chiral molecule is doped into the liquid crystal material corresponding to the first pixel unit, the quantum rods in the first pixel unit have a chiral configuration and emit circularly polarized light. Therefore, light emitted from the display panel is prevented from being absorbed, and a brightness of the display panel is increased.

### DESCRIPTION OF DRAWINGS

FIG. 1 is a schematic structural view showing a conventional display panel.

FIG. 2 is a schematic structural view showing a display panel according to one embodiment of the present disclosure.

FIG. 3 is a schematic structural view showing a display panel according to another embodiment of the present disclosure.

FIG. 4 is a schematic structural view showing a display panel according to yet another embodiment of the present disclosure.

### DETAILED DESCRIPTION

The following description of the various embodiments is provided with reference to the accompanying drawings to demonstrate the embodiments of the present disclosure. The following description of the various embodiments is provided with reference to the accompanying drawings. The embodiments described with reference to the attached drawings are all exemplary and are intended to illustrate and interpret the present disclosure. It should be understood that terms such as “top”, “bottom”, “front”, “rear”, “left”, “right”, “inside”, “outside”, “lateral”, as well as derivatives thereof should be construed to refer to the orientation as then described or as shown in the drawings under discussion. These relative terms are for convenience of description, and shall not be construed as causing limitations to the present disclosure. In the drawings, the identical or similar reference numerals constantly denote the identical or similar elements or elements having the identical or similar functions.

Terms “first”, “second”, etc. in the specification and claims of the present disclosure and the above figures are used to distinguish similar objects, but are not used to describe a specific order. It should be noted that the objects can be interchanged in an appropriate case. In addition, terms “including” and “including” and any variants thereof are intended to cover non-exclusive inclusions.

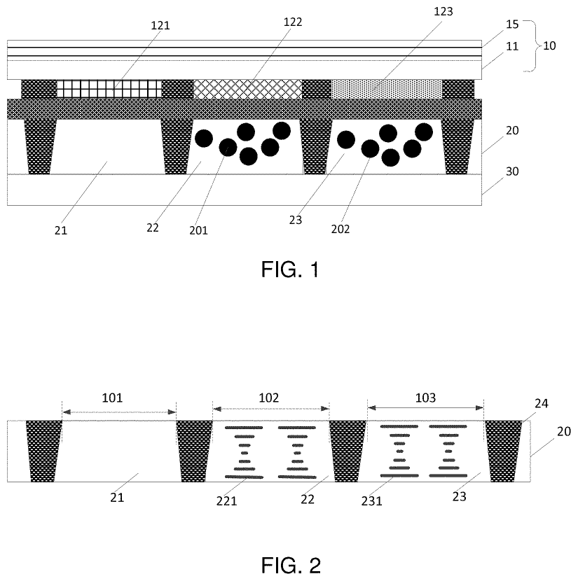

As shown in FIG. 1, a conventional display panel includes a first substrate 10, a liquid crystal layer 20, and a second substrate 30. The liquid crystal layer includes a liquid crystal unit 21, a liquid crystal unit 22, and a liquid crystal unit 23. The first substrate 10 includes a plurality of color resist films, and specifically, includes a blue color resist 121, a red color resist 122, and a green color resist 123. A plurality of red quantum dots 201 are doped into a liquid crystal material in the liquid crystal unit 22 corresponding to the red color resist 122, and a plurality of green quantum dots 202 are doped into a liquid crystal material in the liquid crystal unit 23 corresponding to the green color resist 123. In addition, the first substrate 10 further includes a base plate 11, and a circular polarizer 15 is further disposed on the base plate 11.

As shown in FIG. 2, a display panel of the present embodiment includes a display area and a non-display area, which are not shown in the drawings. The display area is configured to display an image.

The display area includes a first pixel unit 102 and a second pixel unit 103. The first pixel unit may be a red pixel unit, and the second pixel unit may be a green pixel unit. In one embodiment, the display area may further include a third pixel unit. The third pixel unit may be a blue pixel unit. Of course, the display area may further include other pixel areas with other colors (e.g. a yellow pixel unit).

The display panel further includes a liquid crystal layer 20.

The liquid crystal layer 20 includes a liquid crystal unit 21, a liquid crystal unit 22, and a liquid crystal unit 23. Each of the third pixel unit 101, the first pixel unit 102, and the second pixel unit 103 corresponds to one of the liquid crystal units. The third pixel unit 101 corresponds to the liquid crystal unit 21, the first pixel unit 102 corresponds to the liquid crystal unit 22, and the second pixel unit 103 corresponds to the liquid crystal unit 23. The liquid crystal unit 21, the liquid crystal unit 22, and the liquid crystal unit 23 are filled with a liquid crystal material (not shown). A plurality of first quantum rods 221 and a chiral molecule are further doped into the liquid crystal unit 22 corresponding to the first pixel unit 102, and a plurality of second quantum rods 231 are further doped into the liquid crystal unit 23 corresponding to the second pixel unit 103. In one embodiment, the plurality of first quantum rods 221 and a chiral molecule are further doped into the liquid crystal unit 22 corresponding to the first pixel unit 102, and/or the plurality of second quantum rods 231 and the chiral molecule are further doped into the liquid crystal unit 23 corresponding to the second pixel unit 103. The first quantum rods 221 may be red quantum rods, and the second quantum rods 231 may be green quantum rods. The quantum rods and the chiral molecule are not doped into the liquid crystal unit corresponding to the third pixel unit 101.

In one embodiment, each the first quantum rods 221 and the second quantum rods 231 has a spiral arrangement because of the chiral molecule. Preferably, to further increase a brightness of the display panel. A weight percentage concentration of the first quantum rods 221 doped into the liquid crystal material in the corresponding liquid crystal unit 22 is less than or equal to 5%, a weight percentage concentration of the second quantum rods 231 doped into the liquid crystal material in the corresponding liquid crystal unit 23 is less than or equal to 5%, and a weight percentage concentration of the chiral molecule doped into the liquid crystal material in the corresponding liquid crystal unit is less than or equal to 2%. The liquid crystal material includes a plurality of liquid crystal molecules and a plurality of monomers of liquid crystal polymers.

There is an interval between two adjacent liquid crystal units spaced apart from each other, a light-shielding section 24 may further be defined at the between two adjacent liquid crystal units. In one embodiment, a material of the light-shielding section 24 is an opaque photoresist material.

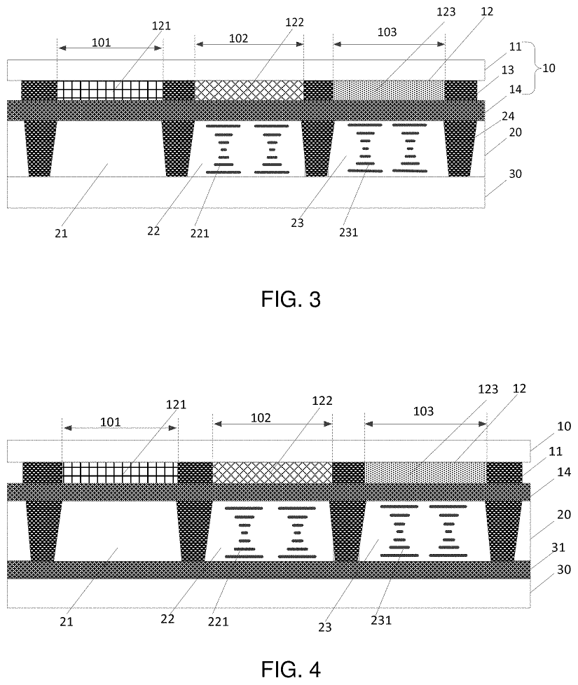

As shown in FIG. 3 and FIG. 4, a sectional structure of the display panel may further include a first substrate 10 and a second substrate 30.

The first substrate 10 is disposed on the liquid crystal layer 20 and includes a base plate 11, a color resist layer 12, and a first alignment film 14.

The base plate 11 may be a glass substrate.

The color resist layer 12 is disposed under the base plate 11 and includes a plurality of color resist films. The color resist films may include a third color resist 121, a first color resist 122, and a second color resist 123. The third color resist 121 corresponds to the third pixel unit 101. The first color resist 122 corresponds to the first pixel unit 102, and the second color resist 123 corresponds to the second pixel unit 103. In one embodiment, the first color resist 122 is a red color resist, the second color resist 123 is a green color resist, and the third color resist 121 is a blue color resist. A black matrix 13 is further disposed between two adjacent color resist films and corresponds to the light-shielding section 24. In one embodiment, the third color resist 121 may correspond to the third pixel unit.

The first alignment film 14 is disposed under the color resist layer 12 and is near the liquid crystal layer 20. The first alignment film 14 is configured to align the liquid crystal molecules. In one embodiment, when the display panel is irradiated with light, a long axis of the liquid crystal molecules is arranged along a horizontal direction, so that a long axis of the quantum dots is arranged along the horizontal direction as well. Because of the chiral molecule, the quantum dots are twisted in a vertical direction and finally form a spiral configuration.

The second substrate 30 is disposed under the liquid crystal layer 20 and includes a plurality of luminescent units (not shown). Each of the third pixel unit 101, the first pixel unit 102, and the second pixel unit 103 corresponds to one of the luminescent units. A color of light emitted from the luminescent units and a color displayed by the third pixel unit (non-display area) are same. Specifically, each of the luminescent units emits blue light. As shown in FIG. 4, in some embodiment, a second alignment film 31 is further disposed on the second substrate 30 and is near the liquid crystal layer 20.

In one embodiment, the second substrate 30 may be an organic light-emitting diode (OLED) substrate specifically including a switch array layer and an organic luminescent display layer. The switch array layer includes a plurality of thin film transistors (TFTs), the organic luminescent display layer includes the plurality of luminescent units, and each of the pixel units corresponds to one of the luminescent units. It should be understood that the OLED may be a micro light-emitting diode.

In one embodiment, the second substrate 30 may be an array substrate. A luminescent module is disposed under the array substrate and includes a plurality of OLED chips, and a position where each of the pixel units is correspondingly disposed is provided with one of the OLED chips. It should be understood that the OLED chips may be micro organic light-emitting chips.

Specifically, in a manufacturing process, a material of the alignment film may be coated on the first substrate, and the alignment film may be formed by rubbing or irradiation with light. The quantum dots and the chiral molecule are doped into the liquid crystal material. Then, the liquid crystal material is printed on the corresponding pixel units. The quantum dots form a spiral configuration because of the chiral molecule. Specifically, the quantum dots are spirally arranged in the vertical direction, thereby emitting circularly polarized light.

Since the chiral molecule are doped into the liquid crystal material corresponding to the first pixel unit, the quantum dots in the liquid crystal material corresponding to the first pixel unit form the spiral configuration, and thereby emits circularly polarized light, thus preventing light emitted from the display panel from being absorbed, and increasing the brightness of the display panel. When the liquid crystal material corresponding to the second pixel unit is also doped with the quantum dots and the chiral molecule, the brightness of the display panel can be further increased.

The present disclosure further provides an electronic device, including any one of the above display panels. The electronic device may be an electrical product such as a cell phone or a tablet.

A display panel and an electronic device are provided by the present disclosure. The display panel includes a display area at least including a first pixel unit, a second pixel unit, and a liquid crystal layer. The liquid crystal layer includes a plurality of liquid crystal units. Each of the first pixel unit and the second pixel unit corresponds to one of the liquid crystal units. The liquid crystal unit corresponding to the first pixel unit is further doped with a plurality of first quantum rods and a chiral molecule, and the liquid crystal unit corresponding to the second pixel unit is further doped with a plurality of second quantum rods. Since the chiral molecule is doped into the liquid crystal material corresponding to the first pixel unit, the quantum rods in the first pixel form a chiral configuration and emit circularly polarized light. Therefore, light emitted from the display panel is prevented from being absorbed, and a brightness of the display panel is increased.

The present disclosure has been described with preferred embodiments thereof. The preferred embodiments are not intended to limit the present disclosure, and it is understood that many changes and modifications to the described embodiment can be carried out without departing from the scope and the spirit of the disclosure that is intended to be limited only by the appended claims.

What is claimed is:

1. A display panel, comprising:
a display area, wherein the display area at least comprises a first pixel unit and a second pixel unit; and
a liquid crystal layer comprising a plurality of liquid crystal units, wherein each of the first pixel unit and the second pixel unit is correspondingly provided with one of the liquid crystal units, the liquid crystal unit corresponding to the first pixel unit is doped with a plurality of first quantum rods and a chiral molecule, and the liquid crystal unit corresponding to the second pixel unit is doped with a plurality of second quantum rods.

2. The display panel of claim 1, wherein the liquid crystal unit corresponding to the second pixel unit is doped with the chiral molecule, and both the first quantum rods and the second quantum rods have a spiral arrangement because of the chiral molecule.

3. The display panel of claim 2, wherein the liquid crystal units are further filled with a liquid crystal material, a weight percentage concentration of the first quantum rods doped into the liquid crystal material in the corresponding liquid crystal unit is less than or equal to 5%, and a weight percentage concentration of the second quantum rods doped into the liquid crystal material in the corresponding liquid crystal unit is less than or equal to 5%.

4. The display panel of claim 2, a weight percentage concentration of the chiral molecule doped into the liquid crystal material in the corresponding liquid crystal unit is less than or equal to 2%.

5. The display panel of claim 1, further comprising:
a first substrate disposed on the liquid crystal layer, wherein the first substrate comprises a first alignment film near the liquid crystal layer.

6. The display panel of claim 5, wherein the first substrate further comprises a base plate and a color resist layer disposed between the first alignment film and the base plate, the color resist layer comprises a plurality of color resist films and a plurality of black matrices, and the black matrices are disposed at a plurality of intervals between two adjacent color resist films; and
a plurality of light-shielding sections are defined at a plurality of intervals between two adjacent liquid crystal units and correspond to the black matrices.

7. The display panel of claim 6, wherein the color resist films comprise a first color resist corresponding to the first pixel unit and a second color resist corresponding to the second pixel unit.

8. The display panel of claim 1, wherein the display area further comprises a third pixel unit.

9. The display panel of claim 8, further comprising:
a second substrate disposed under the liquid crystal layer, wherein the second substrate comprises a plurality of luminescent units, each of the first pixel unit, the second pixel unit, and the third pixel unit corresponds to one of the luminescent units, and a color of light emitted from the luminescent units and a color displayed by the third pixel unit are same.

10. The display panel of claim 9, wherein the second substrate is an organic light-emitting diode (OLED) substrate or an array substrate.

11. An electronic device, comprising a display panel;
wherein the display panel comprises:
a display area, wherein the display area at least comprises a first pixel unit and a second pixel unit; and
a liquid crystal layer comprising a plurality of liquid crystal units, wherein each of the first pixel unit and the second pixel unit is correspondingly provided with one of the liquid crystal units, the liquid crystal unit corresponding to the first pixel unit is doped with a plurality of first quantum rods and a chiral molecule, and the liquid crystal unit corresponding to the second pixel unit is doped with a plurality of second quantum rods.

12. The electronic device of claim 11, wherein the liquid crystal unit corresponding to the second pixel unit is doped with the chiral molecule, and both the first quantum rods and the second quantum rods have a spiral arrangement because of the chiral molecule.

13. The electronic device of claim 12, wherein the liquid crystal units are further filled with a liquid crystal material, a weight percentage concentration of the first quantum rods doped into the liquid crystal material in the corresponding liquid crystal unit is less than or equal to 5%, and a weight percentage concentration of the second quantum rods doped into the liquid crystal material in the corresponding liquid crystal unit is less than or equal to 5%.

14. The electronic device of claim 12, a weight percentage concentration of the chiral molecule doped into the liquid crystal material in the corresponding liquid crystal unit is less than or equal to 2%.

15. The electronic device of claim 11, wherein the display panel further comprises:
a first substrate disposed on the liquid crystal layer, wherein the first substrate comprises a first alignment film near the liquid crystal layer.

16. The electronic device of claim 15, wherein the first substrate further comprises a base plate and a color resist layer disposed between the first alignment film and the base plate, the color resist layer comprises a plurality of color resist films and a plurality of black matrices, and the black matrices are disposed at a plurality of intervals between adjacent two of the color resist films; and
a plurality of light-shielding sections are defined at a plurality of intervals between adjacent two of the liquid crystal units and correspond to the black matrices.

17. The electronic device of claim 16, wherein the color resist films comprise a first color resist corresponding to the first pixel unit and a second color resist corresponding to the second pixel unit.

18. The electronic device of claim 11, wherein the display area further comprises a third pixel unit.

19. The electronic device of claim 18, wherein the display panel further comprises:
a second substrate disposed under the liquid crystal layer; and
the second substrate comprises a plurality luminescent units, each of the first pixel unit, the second pixel unit, and the third pixel unit corresponds to one of the luminescent units, and a color of light emitted from the luminescent units and a color displayed by the third pixel units are same.

20. The electronic device of claim 19, wherein the second substrate is an organic light-emitting diode (OLED) substrate or an array substrate.
